(19) United States
(12) Patent Application Publication
(10) Pub. No.: US 2024/0026186 A1
(43) Pub. Date: Jan. 25, 2024

(54) COATED ARTICLE WITH QUASI-CERAMIC BASECOAT CURED AT LOW TEMPERATURES

(71) Applicant: Vapor Technologies, Inc., Longmont, CO (US)

(72) Inventors: Bryce Randolph ANTON, Longmont, CO (US); Barrett POVIRK, Longmont, CO (US)

(73) Assignee: Vapor Technologies, Inc., Longmont, CO (US)

(21) Appl. No.: 18/225,722

(22) Filed: Jul. 25, 2023

Related U.S. Application Data
(60) Provisional application No. 63/369,312, filed on Jul. 25, 2022.

(51) Int. Cl. C09D 183/04; C09D 5/33; C09D 1/00; C09D 7/63; C09D 7/20

(52) U.S. Cl. CPC C09D 183/04; C09D 5/004; C09D 1/00; C09D 7/63; C09D 7/20

(57) ABSTRACT

A method for making a coated article is provided. The method includes a step in which a liquid silicon-containing composition is applied onto a surface of an article to form an uncured silicon-containing layer. The uncured silicon-containing is cured (or allowed to cure) to form a silicon-containing quasi-ceramic layer disposed over and optionally contacting the surface of the article. Characteristically, the silicon-containing quasi-ceramic layer includes a plurality of siloxane units. Advantageously, the silicon-containing quasi-ceramic layer can also include a plurality of metallosiloxane units. A metal-containing layer is applied by physical vapor deposition onto the silicon-containing quasi-ceramic layer.

### CROSS-REFERENCE TO RELATED APPLICATIONS

This application claims the benefit of U.S. provisional application Ser. No. 63/369,312 filed Jul. 25, 2022, the disclosure of which is hereby incorporated in its entirety by reference herein.

### TECHNICAL FIELD

In at least one aspect, the present invention is related to multilayered coated articles with a coating system that includes a quasi-ceramic layer.

### BACKGROUND

Organic polymer coatings such as urethanes have been used within the coating stack in strategies aiming to replace electroplated finishes (see, U.S. Pat. No. 6,730,362). Although these coatings provide good surface “leveling” and corrosion resistance, gouge resistance tends to be poor due to their inherent softness, which results in inadequate mechanical support to the subsequently deposited metallic surface layer. Coated articles with metal coating are disclosed in U.S. Pat. Nos. 6,346,327 and 6,277,494.

Accordingly, there is a need for improved hard polymeric coatings for coating articles that need an outer metallic layer.

### SUMMARY

In at least one aspect, a method for making a coated article is provided. The method includes a step in which a liquid silicon-containing composition is applied to a surface of an article to form an uncured silicon-containing layer. The uncured silicon-containing is cured (or allowed to cure) to form a silicon-containing quasi-ceramic layer disposed over and optionally contacting the surface of the article. Characteristically, the silicon-containing quasi-ceramic layer includes a plurality of siloxane units. Advantageously, the silicon-containing quasi-ceramic layer can also include a plurality of metallosiloxane units. A metal-containing layer is applied by physical vapor deposition onto the silicon-containing quasi-ceramic layer.

In another aspect, a coated article made by the method described above is provided. The coated article includes a silicon-containing quasi-ceramic layer disposed over a substrate. Advantageously, the silicon-containing quasi-ceramic layer includes a plurality of siloxane units and a plurality of metallosiloxane units. A metal-containing layer is disposed over the silicon-containing quasi-ceramic layer.

In another aspect, the quasi-ceramic coatings formed herein are much harder than conventional organic polymer coating and provide good adherence to many different substrate materials.

In still another aspect, the surface energy of the quasi-ceramic coating can be tailored to be hydrophilic (high surface energy) which would allow coatings to adhere readily.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be made to the following detailed description, read in conjunction with the following drawings, wherein like reference numerals denote like elements and wherein:

FIG. 1. Schematic flowchart of a method for making a coated article.

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: all R groups (e.g. R, where i is an integer) include hydrogen, alkyl, lower alkyl, C₁₋₆ alkyl, C₆₋₁₀ aryl, C₆₋₁₀ heteroaryl, alylaryl (e.g., C₁₋₈ alkyl C₆₋₁₀ aryl), —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups, M⁺ is a metal ion, and L⁻ is a negatively charged counter ion; R groups on adjacent carbon atoms can be combined as —OCH₂O—; single letters (e.g., “n” or “o”) are 1, 2, 3, 4, or in the compounds disclosed herein a CH bond can be substituted with alkyl, lower alkyl, C₁₋₆ alkyl, C₆₋₁₀ aryl, C₆₋₁₀ heteroaryl, —NO₂, —NH₂, —N(R′R″), —N(R′R″R′″)⁺L⁻, Cl, F, Br, —CF₃, —CCl₃, —CN, —SO₃H, —PO₃H₂, —COOH, —CO₂R′, —COR′, —CHO, —OH, —OR′, —O⁻M⁺, —SO₃⁻M⁺, —PO₃⁻M⁺, —COO⁻M⁺, —CF₂H, —CF₂R′, —CFH₂, and —CFR′R″ where R′, R″ and R′″ are C₁₋₁₀ alkyl or C₆₋₁₈ aryl groups, M⁺ is a metal ion, and L⁻ is a negatively charged counter ion; hydrogen atoms on adjacent carbon atoms can be substituted as —OCH₂O—; when a given chemical structure includes a substituent on a chemical moiety (e.g., on an aryl, alkyl, etc.) that substituent is imputed to a more general chemical structure encompassing the given structure; percent, “parts of,” and ratio values are by weight; the term “polymer” includes “oligomer,” “copolymer,” “terpolymer,” and the like; molecular weights provided for any polymers refers to weight average molecular weight unless otherwise indicated; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “about” means that the amount or value in question may be the specific value designated or some other value in its neighborhood. Generally, the term “about” denoting a certain value is intended to denote a range within +/−5% of the value. As one example, the phrase “about 100” denotes a range of 100+/−5, i.e. the range from 95 to 105. Generally, when the term “about” is used, it can be expected that similar results or effects according to the invention can be obtained within a range of +/−5% of the indicated value.

As used herein, the term “and/or” means that either all or only one of the elements of said group may be present. For example, “A and/or B” shall mean“only A, or only B, or both A and B.” In the case of “only A,” the term also covers the possibility that B is absent, i.e. “only A, but not B.”

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The phrase “composed of” means “including” or “consisting of” Typically, this phrase is used to denote that an object is formed from a material.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” and “multiple” as a subset. In a refinement, “one or more” includes “two or more.”

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numeral quantity, in a refinement, the term “less than” includes a lower non-included limit that is 5 percent of the number indicated after “less than.” For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, or 1 percent of the number indicated after “less than.”

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

For all compounds expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-2.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

The term “residue” means a portion, and typically a major portion, of a molecular entity, such as a molecule or a part of a molecule such as a group, which has underwent a chemical reaction and is now covalently linked to another molecular entity. In a refinement, the term “residue” means an organic structure that is incorporated into the polymer by polymerization involving the corresponding monomer. In another refinement, the term “residue” when used in reference to a monomer or monomer unit means the remainder of the monomer unit after the monomer unit has been incorporated into the polymer chain. When a polymer component or a portion thereof does not react when included in a combination, the residue is the unreacted polymer component in reference to the combination.

Throughout this application, where publications are referenced, the disclosures of these publications in their entireties are hereby incorporated by reference into this application to more fully describe the state of the art to which this invention pertains.

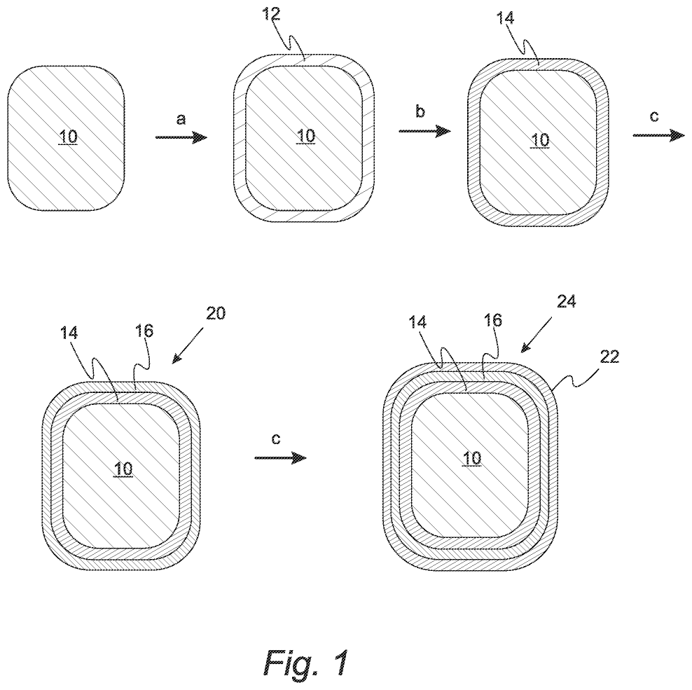

Referring to FIG. 1, a flowchart depicting a method for coating an article. In step a), a liquid silicon-containing composition is applied onto a surface of article 10 to form an uncured silicon-containing layer 12. The liquid silicon-containing composition includes the components described below in predetermined amounts with the balance of the composition being a solvent such the viscosity is suitable for coating the article. In a refinement, the liquid silicon-containing composition has a viscosity from about 0.1 to 50 MPa at 25° C. The article can be made from virtually any desired material such as plastic, ceramic, metal, or metal alloy. The liquid composition can be applied by any suitable technique such as dip coating, spraying, and brushing. In step b), the uncured silicon-contain containing 12 is cured (or allowed to cure) to form a silicon-containing quasi-ceramic layer 14 disposed over and optionally contacting the surface of article 10. In a refinement, the uncured silicon-containing layer is cured at a temperature less than about 50° C. In a further refinement, the uncured silicon-containing layer is cured under ambient conditions (e.g., 20 to 30° C.). Characteristically, the silicon-containing quasi-ceramic layer 14 includes a plurality of siloxane units. In a variation, the silicon-containing quasi-ceramic layer 14 further includes a plurality of metallosiloxane units. In step c), a metal-containing layer 16 is applied by physical vapor deposition onto the silicon-containing quasi-ceramic layer. Examples of physical vapor deposition techniques include sputtering, evaporation, cathodic arc deposition, and the like. In a variation as depicted in step d), a top layer 22 over the metal-containing layer is applied as a protective layer. In a refinement, the top layer 22 being composed of a quasi-ceramic material. Details of forming a quasi-ceramic layer are found in U.S. Pat. No. 10,633,556; the entire disclosure of which is hereby incorporated by reference.

In a variation, the metal-containing layer is composed of a refractory metal or refractory metal alloy. Examples of refractory metals or refractory metal alloys include but are not limited to chromium, nickel, tungsten, zirconium, aluminum, nickel alloys, and combinations thereof. In a refinement, the metal-containing layer is composed of chromium, nickel, tungsten, zirconium, copper, steel, brass, zinc, aluminum, nickel alloys, titanium, gold, silver, and combinations thereof.

In another variation, the metal-containing layer is composed of a component selected from the group consisting of a chromium nitride, chromium carbide and chromium carbonitride.

In another variation, the metal-containing layer is composed of a component selected from the group consisting of a metal oxide, a metal nitride, and a metal carbonitride. In a refinement, the metal-containing layer is composed of a component selected from the group consisting of zirconium nitride (ZrN), zirconium carbide, zirconium carbonitride (ZrCN), zirconium oxycarbide (ZrOC), zirconium aluminum nitride (ZrAlN), and zirconium silicon carbonitride (ZrSiCN).

In a refinement, the metal-containing layer includes zirconium, carbon and nitrogen where zirconium is present in an amount of at least 50 mole percent with each of the carbon and nitrogen present in an amount of at least 0.02 and 0.1 mole percent, respectively. In a refinement, the metal containing layer includes a compound having the following formula:

Zr_{1-x-y}CₓN_{y}.

where x is 0.0 to 0.3 and y is 0.1 to 0.5. In a refinement, x is 0.0 to 0.2 and y is 0.2 to 0.3. In another refinement, x is at least in increasing order of preference 0.0, 0.02, 0.03, 0.04, 0.05, 0.07, or 0.09 and at most in increasing order of preference, 0.5, 0.4, 0.3, 0.25, 0.2, 0.15, or 0.11. Similarly, in this refinement, y is at least in increasing order of preference 0.1, 0.15, 0.2, 0.25, 0.27, or 0.29 and at most in increasing order of preference, 0.6, 0.5, 0.40, 0.35, 0.33, or 0.31. In a further refinement, metal containing layer includes zirconium carbonitride described by Zr_{0.60}C_{0.10}N_{0.30}.

In a variation, the liquid silicon-containing composition includes a silicon-containing compound selected from the group consisting of an inorganic silicon-containing polymer, an inorganic silicon-containing oligomer, and an inorganic silicon-containing compound dissolved in a solvent. The silicon-containing compound can be present in an amount from about 1 to 20 weight percent of the total weight of the liquid silicon-containing composition. In a refinement, the liquid silicon-containing composition includes a silicone or a polysiloxane. The liquid silicon-containing composition can include a component selected from the group consisting of optionally substituted silazanes, siloxanes, carbosilanes, and combinations thereof. In a refinement, the liquid silicon-containing composition can include an organopolysilazane.

In a variation, the liquid silicon-containing composition further includes an organometallic compound. The organometallic compound can be present in an amount from about 0.1 to 10 weight percent of the total weight of the liquid silicon-containing composition. In a refinement, the organometallic compound can be present in an amount from about 1 to 10 weight percent of the total weight of the liquid silicon-containing composition. Examples of organometallic compound include but are not limited to zirconium tert-butoxide, tantalum ethoxide, silver neodecanoate, titanium butoxide, tungsten ethoxide, aluminum-tri-sec-butoxide, and combinations thereof.

In a variation, the liquid silicon-containing composition further includes an alkoxysilane. The alkoxysilane can be present in an amount from about 0.1 to 10 weight percent of the total weight of the liquid silicon-containing composition. Examples of alkoxysilane include but are not limited to 3-aminopropyltrimethoxysilane, glycodioxypropyltrimethoxysilane, 1H,1H,2H,2H-perfluorooctyltriethoxysilane, 1H,1H,2H,2H-perfluorodecyltrimethoxysilane, 1H,1H,2H,2H-perfluorodecyltriethoxysilane, octadecyldimethyl (3-trimethoxy silylpropyl) ammonium chloride, N-(2-aminoethyl)3-aminopropyl-trimethoxysilane, N-(2-aminoethyl)3-aminopropyl-triethoxysilane, or combinations thereof.

In another variation, the solvent is an aprotic solvent. Examples of solvents include but are not limited to hexamethyldisiloxane, hexamethylcyclotrisiloxane, octamethyltrisiloxane, octamethylcyclotetrasiloxane, decamethyltetrasiloxane, decamethylcyclopentasiloxane, dodecamethylpentasiloxane, dodecamethylcyclohexasiloxane, tetradecamethylhexasiloxane, t-butyl acetate, n-butyl acetate, ethyl acetate, xylene, petroleum benzene, dipropylene glycol dimethyl ether, dipropylene glycol dibutyl ether, 1-methoxy-2-propyl acetate, 2-butoxyethyl acetate, 2-(2-butoxyethoxy) ethyl acetate, naphtha, dibutylether, and combinations thereof.

Referring to FIG. 1, a coated article made by the method described above is also provided. Coated article 20 includes silicon-containing quasi-ceramic layer 14 disposed over the substrate 10 (i.e., the uncoated article). As set forth above, the substrate is composed of a plastic, ceramic, metal, or metal alloy. Advantageously, the silicon-containing quasi-ceramic layer includes a plurality of siloxane units and optionally, a plurality of metallosiloxane units. Metal-containing layer 16 is disposed over the silicon-containing quasi-ceramic layer 14. In a variation, coated article 24 further includes top layer 22 as set forth above. The details for the metal-containing layer are set forth above. In certain variations, the silicon-containing quasi-ceramic layer includes residues of each of the components of the liquid silicon-containing composition that remain after curing.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A method for coating an article comprising:
applying a liquid silicon-containing composition onto a surface of the article to form an uncured silicon-containing layer;
curing the uncured silicon-containing layer to form a silicon-containing quasi-ceramic layer disposed over the surface of the article, the silicon-containing quasi-ceramic layer including a plurality of siloxane units; and
applying a metal-containing layer by physical vapor deposition onto the silicon-containing quasi-ceramic layer.

2. The method of claim 1 further comprising applying a top layer over the metal-containing layer as a protective layer, the top layer being composed of a quasi-ceramic material.

3. The method of claim 1 wherein the silicon-containing quasi-ceramic layer further includes a plurality of metallosiloxane units.

4. The method of claim 1 wherein the metal-containing layer is composed of a refractory metal or refractory metal alloy.

5. The method of claim 1 wherein the metal-containing layer is composed of chromium, nickel, tungsten, zirconium, copper, steel, brass, zinc, aluminum, nickel alloys, titanium, gold, silver, and combinations thereof.

6. The method of claim 1, wherein the metal-containing layer is composed of a component selected from the group consisting of a metal oxide, a metal nitride, and a metal carbonitride.

7. The method of claim 1, wherein the metal-containing layer is composed of a component selected from the group consisting of a chromium nitride, chromium carbide and chromium carbonitride.

8. The method of claim 1, wherein the metal-containing layer is composed of a component selected from the group consisting of zirconium nitride (ZrN), zirconium carbide, zirconium carbonitride (ZrCN), zirconium oxycarbide (ZrOC), zirconium aluminum nitride (ZrAlN), and zirconium silicon carbonitride (ZrSiCN).

9. The method of claim 1 wherein the uncured silicon-containing layer is cured at a temperature less than about 50° C.

10. The method of claim 1 wherein the uncured silicon-containing layer is cured under ambient conditions.

11. The method of claim 1 wherein the liquid silicon-containing composition includes an inorganic silicon-containing polymer, an inorganic silicon-containing oligomer, or an inorganic silicon-containing compound dissolved in a solvent.

12. The method of claim 11, wherein the liquid silicon-containing composition includes a silicone or a polysiloxane.

13. The method of claim 11, wherein the liquid silicon-containing composition includes a component selected from the group consisting of optionally substituted silazanes, siloxanes, carbosilanes, and combinations thereof.

14. The method of claim 9, wherein the liquid silicon-containing composition further includes an organometallic compound.

15. The method of claim 14, wherein the organometallic compound includes a component selected from the group consisting of zirconium tert-butoxide, tantalum ethoxide, silver neodecanoate, titanium butoxide, tungsten ethoxide, aluminum-tri-sec-butoxide, and combinations thereof.

16. The method of claim 11, wherein the liquid silicon-containing composition further includes an alkoxysilane.

17. The method of claim 16, wherein the alkoxysilane is selected from the group consisting of 3-aminopropyltrimethoxysilane, glycodioxypropyltrimethoxysilane, 1H, 1H,2H,2H-perfluorooctyltriethoxysilane, 1H,1H,2H,2H-perfluorodecyltrimethoxysilane, 1H,1H,2H,2H-perfluorodecyltriethoxysilane, octadecyldimethyl (3-trimethoxy silylpropyl) ammonium chloride, N-(2-aminoethyl)3-aminopropyl-trimethoxysilane, N-(2-aminoethyl)3-aminopropyl-triethoxysilane, or combinations thereof.

18. The method of claim 11, wherein the solvent is an aprotic solvent.

19. The method of claim 18, wherein the solvent comprises hexamethyldisiloxane, hexamethylcyclotrisiloxane, octamethyltrisiloxane, octamethylcyclotetrasiloxane, decamethyltetrasiloxane, decamethylcyclopentasiloxane, dodecamethylpentasiloxane, dodecamethylcyclohexasiloxane, tetradecamethylhexasiloxane, t-butyl acetate, n-butyl acetate, ethyl acetate, xylene, petroleum benzene, dipropylene glycol dimethyl ether, dipropylene glycol dibutyl ether, 1-methoxy-2-propyl acetate, 2-butoxyethyl acetate, 2-(2-butoxyethoxy) ethyl acetate, naphtha, dibutylether, and combinations thereof.

20. A coated article comprising:
a substrate;
a silicon-containing quasi-ceramic layer disposed over the substrate, the silicon-containing quasi-ceramic layer including a plurality of siloxane units and a plurality of metallosiloxane units; and
a metal-containing layer disposed over the silicon-containing quasi-ceramic layer.
